(19) United States
(12) Patent Application Publication
(10) Pub. No.: US 2026/0203483 A1
(43) Pub. Date: Jul. 16, 2026

(54) MACHINE LEARNING BASED SURFACE NETWORK MODELING

(71) Applicant: Schlumberger Technology Corporation, Sugar Land, TX (US)

(72) Inventors: Kassem GHORAYEB, Abu Dhabi (AE); Deniz ALAKOUM, Beirut (LB)

(21) Appl. No.: 19/139,352

(22) PCT Filed: Feb. 16, 2024
(86) PCT No.: PCT/US2024/016255

§ 371 Date: Jun. 15, 2025

Related U.S. Application Data
(60) Provisional application No. 63/485,772, filed on Feb. 17, 2023.

(51) Int. Cl. G06F 30/28

(52) U.S. Cl. CPC G06F 30/28

(57) ABSTRACT

The present disclosure describes techniques including sampling a multidimensional physical space to determine representative combinations of pipeline segment parameters, and executing a flow simulator to estimate pressure drop values or pressure gradient values for pipeline segments having the representative combinations of pipeline segment parameters. The techniques also include training a ML model using the pressure drop values or the pressure gradient values estimated by the flow simulator. The ML model may output a predicted pressure drop value or pressure gradient value for a pipeline segment based on input values representing pipeline segment parameters of the pipeline segment. The techniques can also include upscaling a network model before executing a ML-based network solver to estimate a pressure drop value, a flow rate value, and node pressure values for the network model using the trained ML model.

### CROSS-REFERENCE TO RELATED APPLICATIONS

This application claims priority to U.S. Provisional Application No. 63/485,772, filed on Feb. 17, 2023, which is hereby incorporated in its entirety.

### INTRODUCTION

This disclosure relates generally a machine-learning (ML) pipeline network modeling system that generates a model using pressure drop values or pressure gradient values.

### BACKGROUND

This section is intended to introduce the reader to various aspects of art that may be related to various aspects of the present disclosure, which are described and/or claimed below. This discussion is believed to help provide the reader with background information to facilitate a better understanding of the various aspects of the present disclosure. Accordingly, it is understood that these statements are to be read in this light, and not as admissions of prior art.

Surface network models play an important role in reducing the capital expenditure of oil and gas fields. In the process of designing pipeline networks, pressure drop is a significant parameter to identifying an optimal design. Pressure drop is typically evaluated using common surface network solvers, which rely on pre-generated tables or correlations. However, certain applications, such as performing optimization loops for field development planning, often involve solving numerous network models. As a result, existing solutions can be prohibitively slow and computer resource intensive. Recent success in applying artificial intelligence (AI) and machine learning (ML) to address a variety of complex engineering problems has sparked interest in their possible applications in the petroleum industry.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Certain embodiments of the present disclosure include a method. The method includes sampling a multidimensional physical space to determine representative combinations of pipeline segment parameters. The method also includes executing a flow simulator to estimate pressure drop values or pressure gradient values for pipeline segments having the representative combinations of pipeline segment parameters. Further, the method includes using the pressure drop values estimated by the flow simulator to train a ML model to predict pressure drop values or pressure gradient values for the pipeline segments having the representative combinations of pipeline segment parameters, yielding a trained ML model. Even further, the method includes using the trained ML model in predictive mode by providing, as input to the trained ML model, input values representing the pipeline segment parameters of a pipeline segment, and in response, receiving, as output, a corresponding predicted pressure drop value or a corresponding predicted pressure gradient value for the pipeline segment.

Certain embodiments of the present disclosure include a machine learning (ML) pipeline network modeling system. The system includes at least one memory configured to store a flow simulator and at least one processor configured to execute stored instruction to perform actions. The actions include sampling a multidimensional physical space to determine representative combinations of pipeline segment parameters, and executing the flow simulator to estimate pressure drop values or pressure gradient values for pipeline segments having the representative combinations of pipeline segment parameters. The actions also include using the pressure drop values or the pressure gradient values estimated by the flow simulator to train a ML model to predict pressure drop values or pressure gradient values for the pipeline segments having the representative combinations of pipeline segment parameters, yielding a trained ML model. The actions further include using the trained ML model in predictive mode by providing, as input to the trained ML model, input values representing the pipeline segment parameters of a pipeline segment, and in response, receiving, as output, a corresponding predicted pressure drop value or a corresponding predicted pressure gradient value for the pipeline segment.

Certain embodiments of the present disclosure include a non-transitory, computer-readable medium storing instructions executable by a processor of a computing device. The instructions include instructions to sample a multidimensional physical space to determine representative combinations of pipeline segment parameters, and to execute a flow simulator to estimate pressure drop values or pressure gradient values for pipeline segments having the representative combinations of pipeline segment parameters. The instructions also include instructions to use the pressure drop values or the pressure gradient values estimated by the flow simulator to train a ML model to predict pressure drop values or pressure gradient values for the pipeline segments having the representative combinations of pipeline segment parameters, yielding a trained ML model. The instructions further include instructions to use the trained ML model in predictive mode by providing, as input to the trained ML model, input values representing the pipeline segment parameters of a pipeline segment, and in response, receiving, as output, a corresponding predicted pressure drop value or a corresponding predicted pressure gradient value for the pipeline segment.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWING

These and other features, aspects, and advantages of the present disclosure will become better understood when the following detailed description is read with reference to the accompanying drawings in which like characters represent like parts throughout the drawings, wherein:

FIG. 1 is a diagram illustrating a machine learning (ML) pipeline modeling system, as well as aspects of a surface network model representing an example pipeline network, according to one or more embodiments of this disclosure;

FIG. 2 is a flow diagram illustrating a process by which the ML pipeline network modeling system builds ML models to estimate the pressure drop through a single pipeline segment, according to one or more embodiments of this disclosure;

FIG. 3 is a flow diagram illustrating a process by which the ML pipeline network modeling system uses a ML-based network solver to solve for node pressure, pressure drop, and flow rates through a single pipeline using the ML models, according to one or more embodiments of this disclosure;

FIG. 4 is a flow diagram illustrating a process by which the ML pipeline network modeling system uses a network solver in combination with the ML models to solve for node pressure, pressure drop, and flow rates through an entire pipeline network, according to one or more embodiments of this disclosure;

FIG. 5A is a diagram illustrating an original pipeline model, according to one or more embodiments of this disclosure;

FIG. 5B is a diagram illustrating an upscaled pipeline model for the original pipeline model of FIG. 5A, according to one or more embodiments of this disclosure;

FIG. 5C is a diagram illustrating an original network model, according to one or more embodiments of this disclosure;

FIG. 5D is a diagram illustrating an upscaled network model for the original network model of FIG. 5C, according to one or more embodiments of this disclosure;

FIG. 6 is a flow diagram illustrating a process by which the ML pipeline network modeling system generates combinations of physical parameters based on a first set of inputs, according to one or more embodiments of this disclosure;

FIG. 7 is a flow diagram illustrating a process by which the ML pipeline network modeling system utilizes a flow simulator to estimate a pipeline segment pressure drop for each of the combinations of physical parameters, according to one or more embodiments of this disclosure;

FIG. 8 is a flow diagram illustrating a process by which the ML pipeline network modeling system develops a ML model that predicts pressure drop through a pipeline segment, according to one or more embodiments of this disclosure;

FIG. 9 is a flow diagram illustrating a process by which the ML pipeline network modeling system upscales a pipeline model, according to one or more embodiments of this disclosure; and

FIG. 10A is a schematic representation that illustrates an upscaling angle, while FIG. 10B is a schematic representation that illustrates an alpha (α) evaluation for the upscaling process, according to one or more embodiments of this disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

The drawing figures are not necessarily to scale. Certain features of the embodiments may be shown exaggerated in scale or in somewhat schematic form, and some details of conventional elements may not be shown in the interest of clarity and conciseness. Although one or more embodiments may be preferred, the embodiments disclosed should not be interpreted, or otherwise used, as limiting the scope of the disclosure, including the claims. It is to be fully recognized that the different teachings of the embodiments discussed may be employed separately or in any suitable combination to produce desired results. In addition, one skilled in the art will understand that the description has broad application, and the discussion of any embodiment is meant only to be exemplary of that embodiment, and not intended to intimate that the scope of the disclosure, including the claims, is limited to that embodiment.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements. It should be noted that the term “multimedia” and “media” may be used interchangeably herein.

As used herein, a “pipeline network”, “network system” or “network” refers to a series of pipelines connected in a tree-like structure. As used herein, a “pipeline” refers to a series of connected pipeline segments that extend between a first node (e.g., an inlet node) and a final node (e.g., an outlet node), and includes internal nodes disposed between and coupling together each of the pipeline segments. As such, there is no loop or feedback in the network, such that the fluid travels in only one direction. In other words, each internal node of the network can have several upstream connections (fluid coming in) and only one downstream connection (fluid coming out).

As noted above, in the process of designing networks, pressure drop is a significant parameter to identify the optimal design. However, since pressure drop is typically estimated using surface network solvers that rely on pre-generated tables or correlations, such solutions generally require substantial computing resources (e.g., processing time, memory usage) to solve a surface network model to provide an estimated pressure drop across the network. For certain applications, such as network planning and optimization, surface network models may be repeatedly solved by a surface network solver while the configuration of the network is incrementally modified (e.g., as part of an optimization loop) to determine an optimal configuration for the network. As a result, existing methods of solving surface network models can be prohibitively slow and/or computing resource intensive and, as such, are unable to quickly and efficiently estimate pressure drop, flow rates, and node pressure within a modeled network.

With the foregoing in mind, present embodiments are directed to a ML pipeline network modeling system that enables a modular approach to develop and utilize ML models to predict pressure drop through the pipelines of a network, flow rates through the pipelines of the network, and a pressure at each node of the network, under any network configuration while addressing real-world applications and the underlying physics. The ML models are trained using synthetic data generated by a flow simulator. In addition, the input variables are selected to be common parameters in the field, recognizing that it is useful to have a predictive tool that can estimate pressure drop of a network using the available data and without any modifications. Finally, the developed ML models are integrated into a conventional network solver to yield a ML-based network solver capable of evaluating the pressure drop, not only through pipeline segments and pipelines, but also through entire pipeline networks. In addition to the enhanced efficiency achieved through the use of ML models, certain embodiments of the present technique also enable an upscaling method that reduces the size of the network, as well as the corresponding processing time and computational resource usage to model the network, without significantly impacting the modeled physical behavior of the network or the pipeline modeling results. The disclosed techniques enable dramatically faster and computational resource efficient solving of surface network models relative to existing techniques. This is especially important to network planning and optimization operations, which may involve solving numerous surface network models. As such, applications of the disclosed techniques include, but are not limited to: surface facility layout optimization, field development screening and planning, and pipeline layout optimization. It is envisioned that the techniques disclosed herein could be utilized by oil and gas companies for the production of hydrocarbon products (e.g., crude oil, natural gas), as well as carbon dioxide (CO₂) capturing and sequestration projects.

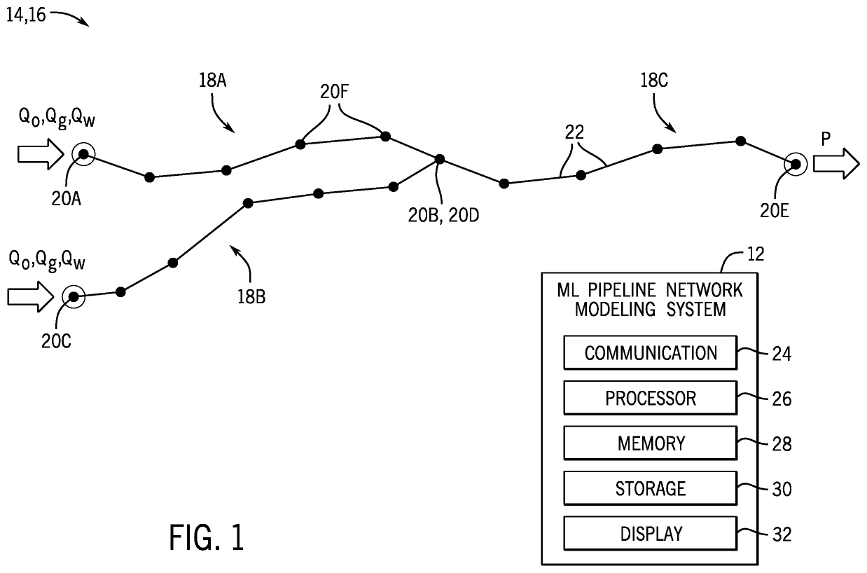

FIG. 1 is a diagram illustrating an embodiment of a machine learning (ML) pipeline modeling system 12, as well as aspects of a surface network model 14 representing an example network 16. The illustrated network 16 includes three pipelines 18: pipeline 18A, pipeline 18B, and pipeline 18C. Pipeline 18A extends from inlet node 20A to outlet node 20B, pipeline 18B extends from inlet node 20C to outlet node 20B, and pipeline 18C extends from inlet node 20D (which is the same as outlet node 20B of pipelines 18A and 18B) to outlet node 20E. Each of the pipelines 18 includes a series of pipeline segments 22 coupled together by internal nodes 20F. With respect to the overall network 16, inlet nodes 20A and 20C of pipelines 18A and 18B may be referred to as inlet boundary nodes, and output node 20E of the pipeline 18C may be referred to as the outlet boundary node of the network 16. In some embodiments, the inlet boundary nodes may be associated with gathering centers of the network 16 that collect the fluid(s) of interest, while the outlet boundary node may be associated with a processing center (e.g., an oil processing center, a gas processing center, a water processing center) of the network 16 that processes the extracted fluid.

More specifically, the surface network model 14 illustrated in FIG. 1 indicates inputs to the pipeline modeling problem, including fluid (e.g., oil, gas, and water) flow rates (e.g., Qₒ, Q_{g}, Q_{w}) at the inlet boundary nodes 20A and 20C, pressure at the outlet boundary node 20E, location of all the nodes 20 in the 3D space, hierarchy of the tree of nodes 20, the location and orientation of each of the pipeline segments 22 in 3D space, and sizing of each of the pipeline segments 22. In some embodiments, the inputs may also include the temperature at the inlet boundary nodes 20A and 20C, as well as the ambient temperature. Given the pressure at the outlet boundary node 20E and the component volumetric flow rates at standard conditions at the inlet boundary nodes 20A and 20C of the network 16, the ML pipeline network modeling system 12 is designed to utilize a ML-based network solver to calculate the pressure at each of the nodes 20, as well as the pressure drop and the volumetric flow rates at standard conditions through each of the pipeline segments 22 and each of the pipelines 18 of the network 16.

The ML pipeline network modeling system 12 may include any suitable computing device, cloud-computing device, or the like and may include various components to perform various analysis operations. As shown in FIG. 1, the ML pipeline network modeling system 12 may include a communication component 24, at least one processor 26, at least one memory 28, at least one storage 30, a display 32, and the like. The communication component 24 may be a wireless or wired communication component that may facilitate communication between different computing systems. The processor 26 may be any type of computer processor or microprocessor capable of executing computer-executable code. The memory 28 and the storage 30 may be any suitable articles of manufacture that can serve as media to store processor-executable code, data, or the like. These articles of manufacture may represent non-transitory computer-readable media (i.e., any suitable form of memory or storage) that may store the processor-executable code used by the processor 26 to perform the presently disclosed techniques.

The display 32 may include any type of electronic display such as a liquid crystal display, a light-emitting-diode display, and the like. As such, data analyzed by the processor 26 may be presented on the display 32, such that the ML pipeline network modeling system 12 may present modeling results. In certain embodiments, the display 32 may be a touch screen display or any other type of display capable of receiving inputs from an operator. Although the ML pipeline network modeling system 12 is described as including the components presented in FIG. 1, the ML pipeline network modeling system 12 should not be limited to including the components listed in FIG. 1. Indeed, the ML pipeline network modeling system 12 may include additional or fewer components than described above. It should also be noted that for the sake of modularity and flexibility, the ML pipeline network modeling system 12 may be implemented over a web application with back-end and front-end components.

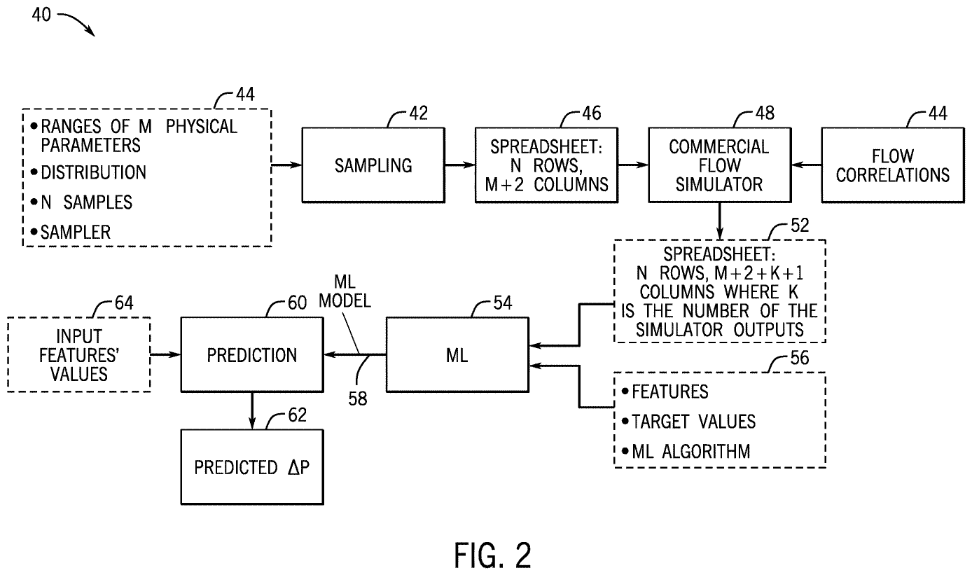

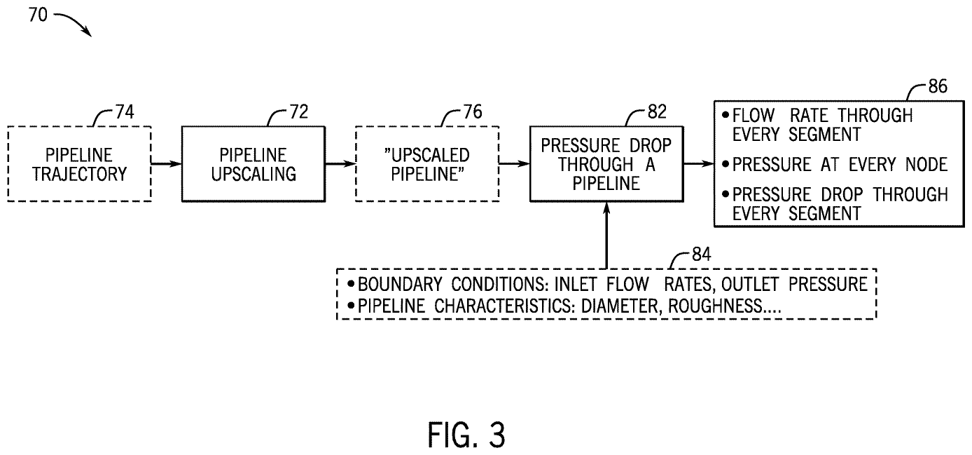

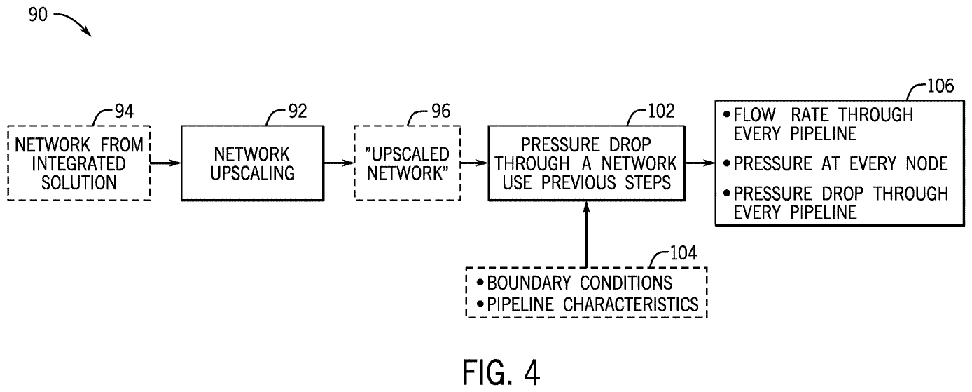

In accordance with the embodiments disclosed herein, the ML pipeline network modeling methodology performed by the ML pipeline network modeling system 12 is divided into three main parts, referred to as Part I, Part II, and Part III. FIGS. 2, 3, and 4 are flow diagrams representing embodiments of processes performed by the processor 26 of the ML pipeline network modeling system 12 during Parts I, II, and III. For example, as illustrated in FIG. 2, Part I involves the ML pipeline network modeling system 12 building ML models to estimate the pressure drop through a single pipeline segment of a network. As illustrated in FIG. 3, Part II involves the ML pipeline network modeling system 12 using a ML-based network solver to solve for node pressure, pressure drop, and flow rates through a single pipeline of the network based on the ML models developed in Part I. As illustrated in FIG. 4, Part III involves the ML pipeline network modeling system 12 using the ML-based network solver of Part II and the ML models of Part I to solve for node pressure, pressure drop, and flow rates through an entire pipeline network.

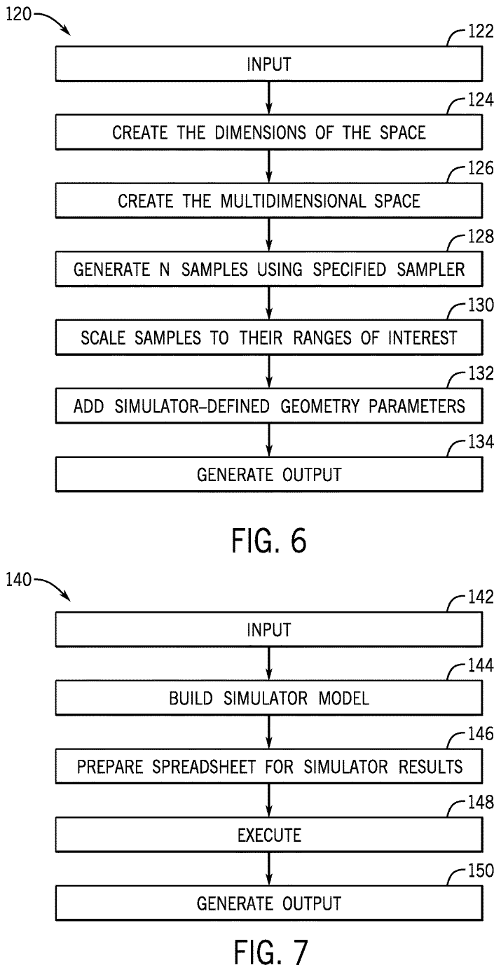

FIG. 2 illustrates an embodiment of a process 40 whereby the processor 26 of the ML pipeline network modeling system 12 determines a pressure drop estimation through a single pipeline segment using a ML model, in accordance with Part I of the overall ML pipeline network modeling process. In some embodiments, each of the steps of the process 40 may be performed by a respective software module of the ML pipeline network modeling system 12. For the illustrated embodiment, the process 40 begins with the processor 26 sampling (block 42) the multidimensional physical space to determine representative combinations of pipeline segment parameters based on a first set of inputs 44 (e.g., ranges of M physical parameters, a distribution, number of samples (N), and a sampler). The actions of block 42 are discussed in detail below with respect to FIG. 6. For the illustrated embodiment, the combinations of pipeline segment parameters are stored within a spreadsheet 46; however, in other embodiments, other suitable data structures (e.g., database tables, comma-separated value (CSV) files) may be used.

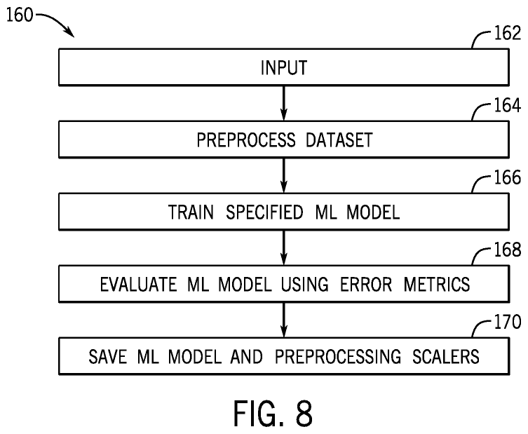

For the embodiment illustrated in FIG. 2, the process 40 continues with the processor 26 preparing (block 48) a synthetic dataset by executing a suitable multiphase flow simulator to estimate a pipeline segment pressure drop for each of the parameter combinations of the spreadsheet 46 determined in block 42 based on a second set of inputs 50 (e.g., flow correlations). The actions of block 48 are discussed in detail below with respect to FIG. 7. For the illustrated embodiment, the spreadsheet 46 generated in block 42 is updated to include the synthetic dataset generated in block 48, yielding an updated spreadsheet 52. The process 40 continues with the processor 26 training (block 54) a ML model to predict pressure drop through a pipeline segment based on the synthetic dataset of the updated spreadsheet 52 generated in block 48 and a third set of inputs 56 (e.g., ML input features, ML target values, ML algorithm), to yield a trained ML model 58. The actions of block 54 are discussed in detail below with respect to FIG. 8. The process 40 concludes with the processor 26 using (block 60) the trained ML model 58 in predictive mode to estimate pressure drop 62 in any pipeline segment defined by a fourth set of inputs 64 (e.g., input values for the features of the trained ML model 58).

FIG. 3 illustrates an embodiment of a process 70 whereby the processor 26 of the ML pipeline network modeling system 12 performs automated single pipeline modeling and pressure drop estimation. In accordance with Part II of the overall ML pipeline network modeling process, the processor 26 executes the process 70 to estimate pressure drops and flow rates through each pipeline segment of a pipeline, as well as the pressure at each node of the pipeline. In some embodiments, each of the steps of the process 70 may be performed by a respective software module of the ML pipeline network modeling system 12.

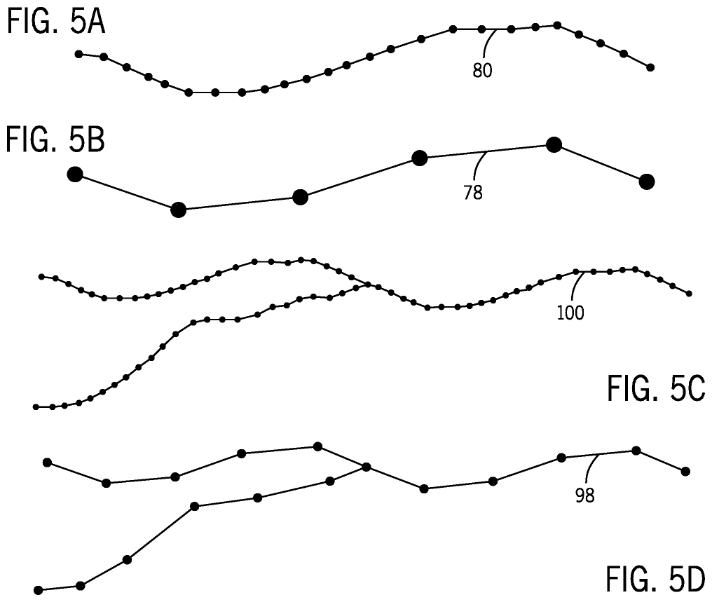

For the illustrated embodiment, the process 70 begins with the processor 26 upscaling (block 72) an original pipeline trajectory 74 based on the inclination and the azimuth angles of the pipeline segments of the pipeline to yield an upscaled pipeline trajectory 76. In general, the goal of block 72 is to upscale the pipeline trajectory into a representative number of connected pipeline segments, such that the number of pipeline segments is decreased in a way that the topology remains representative of the original pipeline trajectory, and such that the pressure drop through the pipeline is neither underestimated nor overestimated. For example, FIG. 5B illustrates an upscaled pipeline model 78 of an original pipeline model 80 illustrated in FIG. 5A. As noted below, the upscaling of block 72 can significantly decrease the processing time while maintaining topology and pressure drop within prescribed tolerance. The actions of block 72 are discussed in detail below. In some embodiments, block 72 may be skipped, and the pipeline is subsequently solved for the original trajectory of the pipeline, without upscaling. At block 82 of the process 70, the processor 26 receives the pipeline trajectory (e.g., original or upscaled), along with user-specified boundary conditions and pipeline characteristics 84, and uses this information to generate a pipeline model. The processor 26 then applies a ML-based network solver, which applies the previously developed ML models (e.g., FIG. 2, block 60) to estimate the pressure drops and the flow rates through the pipeline segments and the pressure at every node of the pipeline model, as indicated by block 86.

FIG. 4 illustrates an embodiment of a process 90 whereby the processor 26 of the ML pipeline network modeling system 12 performs automated surface network modeling and pressure drop estimation for a network. In accordance with Part III, the processor 26 executes the process 90 to estimate pressure drops and flow rates through each pipeline of a pipeline network, as well as the pressure at each node of the network. In some embodiments, each of the steps of the process 90 may be performed by a respective software module of the ML pipeline network modeling system 12.

For the illustrated embodiment, the process 90 begins with the processor 26 upscaling (block 92) original pipeline trajectories 94 of the pipelines of the network, based on the inclination and the azimuth angles of the pipeline segments of each pipeline, to yield an upscaled network model 96. For example, FIG. 5D illustrates an upscaled surface network 98 model of an original surface network model 100 illustrated in FIG. 5C. In some embodiments, the processor 26 may perform the upscaling of block 72 of FIG. 3 for each pipeline of the network to yield the upscaled pipeline trajectories of the network. In some embodiments, block 92 may be skipped, and the network is subsequently solved for the original trajectories of the pipelines, without upscaling. At block 102 of the process 90, the processor 26 receives the pipeline trajectories of the network (e.g., original or upscaled), along with user-specified boundary conditions and pipeline characteristics 104, and uses this information to generate a network model. The processor 26 then applies the ML network solver (e.g., FIG. 3, block 82), which uses the previously developed ML models (e.g., FIG. 2, block 60) to estimate the pressure drops and the flow rates through each pipeline of the network, as well as the pressure at every node of the network model, as indicated by block 106.

### Sampling the Multidimensional Physical Space

As discussed above, block 42 of FIG. 2 involves sampling the multidimensional physical space to determine representative combinations of pipeline segment parameters based on the first set of inputs 44. FIG. 6 is a flow diagram illustrating an embodiment of a process 120 whereby the processor 26 of the ML pipeline network modeling system 12 generates N combinations of physical parameters based on the first set of inputs 44. For the embodiment illustrated in FIG. 6, the process 120 begins with the processor 26 receiving (block 122) the first set of inputs 44. Based on the first set of inputs 44, the processor 26 proceeds to create (block 124) dimensions of the space from the set of M physical parameters of the first set of inputs 44. The processor 26 then creates (block 126) the multidimensional space based on these dimensions. The dimensions are created as real (e.g., float) numbers ranging between zero and one, such that all the parameters are represented in the same way in the space despite having widely different ranges, and every combination of parameters represents a point in the multidimensional space. In some embodiments, the set of parameters includes all the possible input parameters to the flow simulator used in block 48 of FIG. 2, whether or not the parameter is required for execution (i.e., does not have a corresponding default value).

For the embodiment illustrated in FIG. 6, the process 120 continues with the processor 26 generating (block 128) N samples from the multidimensional space using the sampler indicated in the first set of inputs 44. For example, in some embodiments, a Latin hypercube sampler is used to sample the multidimensional space to generate the N samples. In some embodiments, other samplers (e.g., random samplers, orthogonal samplers, Monte Carlo samplers) may be used. The process 120 continues with the processor 26 scaling (block 130) samples to their ranges of interest, as indicated by the ranges of the physical parameters defined in the first set of inputs 44. In some embodiments, the process 120 continues with the processor 26 adding (block 132) simulator-defined geometry parameters to the sampled dataset. For example, in certain embodiments, the flow simulator that will consume the spreadsheet 46 in block 48 of FIG. 2 may require certain parameters that were not generated during the sampling of the multidimensional space, and these parameters are instead derived from the sampled parameters of the dataset. By way of specific example, the flow simulator may expect or require parameter values indicating the horizontal distance of a pipeline segment and the elevation difference between the ends of the pipeline segment, and the processor 26 may use certain sampled parameter values (e.g., inclination angle, segment length) and relevant trigonometry rules to calculate the horizontal distance and the elevation difference of the segment. The process 120 concludes with the processor 26 outputting (block 134) the N sampled combinations of physical parameters into the spreadsheet 46. For the specific example discussed above, the spreadsheet 46 includes N rows (one per sampled parameter combination), and includes M+2 columns (one per physical parameter M, plus extra columns for the calculated horizontal distance and the elevation difference).

### Generating the Synthetic Dataset

As discussed above, block 48 of FIG. 2 involves preparing a synthetic dataset that estimates a respective pressure drop for each of the N combinations of the spreadsheet 46 determined in block 42 based on a second set of inputs 50. FIG. 7 is a flow diagram illustrating an embodiment of a process 140 whereby the processor 26 of the ML pipeline network modeling system 12 executes a flow simulator to estimate a pressure drop for each of the N samples of the spreadsheet 46.

For the embodiment illustrated in FIG. 7, the process 140 begins with the processor 26 receiving inputs (block 142), including the spreadsheet 46 generated in block 48 of FIG. 2 and the second set of inputs 50, which correspond to flow correlations to be applied by the flow simulator to generate the synthetic dataset. For certain embodiments, the flow correlations include vertical multiphase flow correlation, horizontal multiphase flow correlation, and single-phase flow correlation. The processor 26 then executes the flow simulator to build (block 144) a respective physical model for each of the N parameter combinations of the spreadsheet, wherein the physical model includes an inlet connected to an outlet via a pipeline segment. In some embodiments, the flow simulator may be operated in batch mode (e.g., using a Python toolkit). The processor 26 further creates a suitable fluid model (e.g., a black oil model), which is assigned to the respective inlets of each physical model. Additionally, the simulation settings are set where the input flow correlations are defined.

For the embodiment illustrated in FIG. 7, the process 140 continues with the processor 26 preparing (block 146) the spreadsheet 46 for the simulator results. For example, the processor 26 may modify the spreadsheet 46 to include additional columns to accommodate the synthetic data that will be generated by the flow simulator for each parameter combination of the spreadsheet. The processor 26 then executes (block 148) the flow simulator to perform a flow simulation with respect to each parameter combination indicated in the spreadsheet 46, and the results (synthetic data) are stored within to yield the updated spreadsheet 52. When a parameter combination of the spreadsheet 46 is unsolvable by the flow simulator, a “not a number” notation (e.g., “NaN”) may instead be stored in the updated spreadsheet 52 for the synthetic data of the parameter combination.

### Training ML Models

As discussed above, block 54 of FIG. 2 involves training a ML model to predict pressure drop through a pipeline segment based on the synthetic dataset of the updated spreadsheet 52 generated in block 48 and a third set of inputs 56. FIG. 8 is a flow diagram illustrating an embodiment of a process 160 whereby the processor 26 of the ML pipeline network modeling system 12 develops a ML model that predicts pressure drop through a pipeline segment.

For the embodiment illustrated in FIG. 8, the process 160 begins with the processor 26 receiving inputs (block 162), including the updated spreadsheet 52 generated in block 54 of FIG. 2 and the third set of inputs 56, which correspond to ML input features on which the ML model will be trained, the ML target values to be predicted by the ML model, and an indication of the ML algorithm (e.g., the type of ML model) to be used. The ML input features and the ML target values are discussed below. In some embodiments, the ML algorithms include random forest (RF), support vector regression (SVR), and/or artificial neural network (ANN). The process 160 continues with the processor 26 preprocessing (block 164) the dataset in the updated spreadsheet 52. For example, preprocessing may include removing entries from the updated spreadsheet 52 that were unsolvable by the flow simulator (e.g., “NaN” entries), scaling the remaining entries using standard scaling techniques, and splitting the remaining entries for training (e.g., 80% of entries) and testing (e.g., 20% of entries).

For the embodiment illustrated in FIG. 8, the process 160 continues with the processor 26 using the specified ML algorithm to train (block 166) a ML model predict the pressure drop through a single pipeline segment. It may be appreciated that each ML algorithm (e.g., RF, SVR, ANN) has a respective set of hyperparameters that are tuned based on the preprocessed dataset. The process 160 continues with the processor 26 evaluating (block 168) the ML model using error metrics. For example, in some embodiments, the processor 26 may evaluate regression models using the mean square error (MSE), R2 score, max percentage error (Max PE), and mean absolute percentage error (MAPE), wherein error is calculated relative to the pressure drop predicted by the flow simulator. The process 160 concludes with the processor 26 saving (block 170) the trained ML model within the memory 28 or storage 30 of the ML pipeline network modeling system 12. In addition, the processor 26 further saves the scalers for both the ML features and ML target values, such that the ML features and ML target values can be scaled using the mean and standard deviation of their dataset when the ML model is used in predictive mode in block 60 of FIG. 2.

### ML Algorithms—ANN Settings

For the example embodiments discussed herein that utilize an ANN ML model, all neurons of the hidden layers use the rectified linear unit (ReLU) as an activation function, whereas the neurons of the output layer use a linear activation function. The adaptive moment estimation Adam optimizer for the gradient descent is used in the back-propagation procedure with a learning rate of 0.001. The number of layers and neurons are obtained via a process of hyperparameter tuning for optimal training, validation, and test set performance. For the example embodiments, the number of layers tested is between 3 and 5. When constructing the ANN, all layers are initially tested with the same number of neurons in each layer, wherein the number of neurons is fairly high. Subsequently, the number of neurons in one or more layers is decreased while monitoring the performance of the training and testing scores.

### ML Algorithms—SVR Settings

For the example embodiments discussed herein that utilize a SVR ML model, the radial basis function (RBF) kernel is used as the nonlinear kernel function. When training a SVR ML model with RBF kernel, two parameters are considered: C and gamma. The parameter C, common to all SVR kernels, trades off misclassification of training examples against simplicity of the decision surface. A low C value renders the decision surface smooth, while a high C value aims at correctly classifying all training examples. Gamma defines the amount of influence a single training example. When the gamma value is high, nearby points will have substantial influence, while a low gamma value results in far-away points also being considered to determine the decision boundary.

It is also recognized that proper choice of C and gamma is important to the SVR's performance. For the example embodiments that include SVR ML models, the grid search and cross validation approach are adopted to identify the best combination of C and gamma values. The grid search procedure passes through all various combinations of hyperparameter values and, on each iteration, trains the SVR ML model on the training dataset and tests the trained algorithm on the testing part of the dataset. Finally, the grid search algorithm chooses the optimal combination of hyperparameters that yields the best score on the testing dataset. The term score refers to the value of the metric that is applied in regression. Instead of dividing the dataset on the training and the testing part once, a cross validation technique may be applied. In this procedure, the dataset is divided into P equal parts, where P-I partitions are used as a training dataset, and the remaining partition as a validation dataset. This process is repeated P times, and on each iteration, a different validation partition is used. As a result, it is possible to compute P test scores, which are then averaged. The average score is used in the grid search algorithm for identifying what set of hyperparameters is the optimal, and these optimal hyperparameters are subsequently used to develop the ML model. The C and gamma values are spaced exponentially far apart with a cross validation folds of 5. For the example embodiments that include SVR ML models, the C range is between 0.1 and 1000, and the gamma range is between 0.0001 and 10, including “scale” and “auto” options, which are equal to 1/(number of features*variance of input features values) and 1/number of features, respectively.

### ML Algorithms—RF Settings

For the example embodiments discussed herein that utilize a RF ML model, the following hyperparameters are adjusted: the number of trees in the forest (n estimators) and number of features that algorithm considers in the process of tree construction (max features). The number of trees must be set high, so its value is searched in the range [100 (default)−1000]. The max features is searched between the options “auto”, “sqrt”, and “log 2”. When “auto” is selected, then max features is equal to the number of features; when “sqrt” is selected, then max features is equal to the square root of the number of features; and when “log 2” is selected, then max features is equal to the base 2 log of the number of features. Similar to SVR, the hyperparameters are tuned using grid search approach with cross validation folds of 5.

### ML Input Features

To identify the input features to ML models, the M parameters in block 42 of FIG. 2 were studied to identify the ones that significantly affect the pressure drop. To do so, a synthetic dataset of 10,000 samples was generated using the Latin hypercube sampler, as discussed above, and the resulting correlation matrix was studied. The 10,000 samples dataset included the M parameters and their ranges are presented in Table 1. Each parameter is listed in Table 1, along with the type (e.g., required or default), the range of values, and the unit of each parameter. The ranges of water and gas specific gravity (SG) are identified from the minimum and maximum acceptable values in the flow simulator. The pipeline geometry defined by horizontal distance and elevation difference in the simulator is represented in the dataset using length and inclination angle parameters.

TABLE 1
M physical parameters used to generate a sensitivity dataset
(SFC/STB = standard cubic foot per stock tank barrel;
STB/D = stock tank barrels per day)

| Parameter | Type | Range |
|---|---|---|
| Outlet pressure (psia) | Required | 100-1,000 |
| Inlet liquid flow rate (STB/D) | Required | 2,000-20,000 |
| Gas-oil ratios (GOR) (SCF/STB) | Required | 300-1,000 |
| Inlet temperature (° F.) | Required | 60-260 |
| Water Cut (WCT) (%) | Default | 0-100 |
| ID (in) | Required | 3-18 |
| Roughness (in) | Default | 0.001-0.1 |
| Length (ft) | Required | 5,000-20,000 |
| Inclination angle (°) | Required | −15-15 |
| Oil API gravity (°API) | Default | 20-60 |
| Water SG | Default | 0.5-2 |
| Gas SG | Default | 0.4-2 |
| Wall thickness (in) | Default | 0.1-5 |
| Rate of undulations | Default | 0-100 |

Based on the correlation matrix determined for the synthetic dataset, the inclination angle, inner diameter (ID), inlet liquid flow rate, and pipeline length showed the highest correlation, indicating their significant influence on the pressure drop. As a result, for present embodiments, the four main parameters that are considered in the set of ML input features are inclination angle, inner diameter (ID), inlet liquid flow rate, and pipeline segment length. The remaining parameters can also be added depending on the requirements of the model under study.

It is noted that the outlet pressure parameter was not considered in the ML input features, as its correlation coefficient with pressure drop was low. However, it is presently recognized that the outlet pressure plays a significant role when solving a network of pipelines, where the inlet pressure to a pipeline is equal to the outlet pressure of the preceding pipeline. Hence, the outlet pressure values are not specific to a single value. As such, it is presently recognized that developing a ML model to predict pressure drop through a pipeline with a constant outlet pressure value would fail to predict correct pressure drop values, resulting in substantial errors between the flow simulated and the ML predicted pressure drop vales. Thus, for present embodiments, the outlet pressure parameter should be added to the set of ML input features. Therefore, in certain embodiments, the minimum ML input features include at least the outlet pressure, inlet liquid flow rate, inner diameter (ID), length, and inclination angle.

In a set of studies, SVR, RF, and ANN ML models were developed, as discussed above, and the prediction performance of the models was evaluated. In general, the ANN ML models demonstrated superior performance relative to the SVR and RF algorithms. In one study, it was observed that the ML models demonstrated in high percentage error (PE) values when the entire inclination angle range is not sufficiently represented within the sampled dataset. To address this issue, in certain embodiments, multiple ML models (e.g., multiple ANN models) are developed to separately address pipeline segments having horizontal, uphill, and downhill inclinations, improving the predictions of the ML models.

In another study, it was observed that the ML models demonstrated high PE values for testing samples representing a low inlet liquid flow rate flowing in a large inner diameter pipeline segment, and for samples representing a high inlet liquid flow rate flowing in small inner diameter pipeline segment. To address this issue, in certain embodiments, a pressure gradient analysis process is used to ensure that the processor 26 of the ML pipeline network modeling system 12 identifies suitable flow rate ranges for each ID under study. This pressure gradient analysis process involves performing additional steps after the actions of blocks 42 and 48 of FIG. 2, in which the updated spreadsheet 52 is further modified to extract samples within a specified pressure gradient range, and to develop an inlet liquid flow rate vs. inner diameter envelope based on the variations in minimum inlet liquid flow rate and maximum inlet liquid flow rate as a function of ID. This envelope can then be used to identify the proper inlet liquid flow rate range for any ID under study, and the corresponding ranges used to generate the synthetic dataset for developing ML models.

In another study, high PE values were observed for ML models developed to address pipeline segments having length ranges from 100 ft to 1,000 ft and from 1,000 ft to 5,000 ft. To address this issue, in certain embodiments, the ML models are trained to predict pressure gradient instead of pressure drop, which results in substantial reduction in PE values. The reason for such improvement is the narrow range of values of pressure gradient compared to pressure drop for pipeline segments of such lengths. It should be noted that whenever the pressure gradient is predicted by ML models instead of pressure drop, the pressure drop is evaluated by multiplying the pressure gradient and the pipeline segment length.

### Using the Trained ML Model in Predictive Mode

As discussed above, block 60 of FIG. 2 involves using the trained ML model in predictive mode to estimate pressure drop in any pipeline segment. The inputs to the ML model in predictive mode include feature values that correspond to the features of the trained ML model. It may be appreciated that the feature values should be within the ranges of the dataset used in developing the ML model. During operation, the trained ML model and corresponding scalers are first loaded into the memory 28 of the ML pipeline network modeling system 12. Then, the feature values are provided as input to the ML model and a pressure drop value is provided as output. The pressure drop value is subsequently scaled using the loaded scaler. The ML model is able to approximate the value of the pressure drop that would be obtained from the flow simulator, but more quickly and using fewer computing resources. It should be noted that whenever the pressure gradient is predicted from ML models instead of pressure drop, as discussed above, the pressure drop is evaluated by multiplying the pressure gradient with the segment length.

### Upscaling a Segmented Pipeline

As discussed above, in block 72 of FIG. 3, a pipeline trajectory may optionally be upscaled before being solved. In general, the goal of block 72 is to upscale the pipeline trajectory into a representative number of connected pipeline segments, such that the number of pipeline segments is decreased (e.g., by 40% or greater, 50% or greater, 60% or greater, 70% or greater, 80% or greater, or 90% or greater, etc.) in a way that the topology remains representative of the original pipeline trajectory, and such that the pressure drop through the pipeline is neither underestimated nor overestimated (e.g., the pressure drop may remain within a tolerance less than or equal to 1%, less than or equal to 2%, less than or equal to 3%, less than or equal to 4%, or less than or equal to 5%). The purpose of this optional step is to significantly decrease the processing time and computing resource usage, while maintaining topology and pressure drop within prescribed tolerance. For example, in some instances, upscaling may decrease the processing time by up to 98%. It should be noted that the above-described examples percentages (e.g., corresponding to the decrease in the number of pipeline segments, the pressure drop, and the processing time) are non-limiting examples.

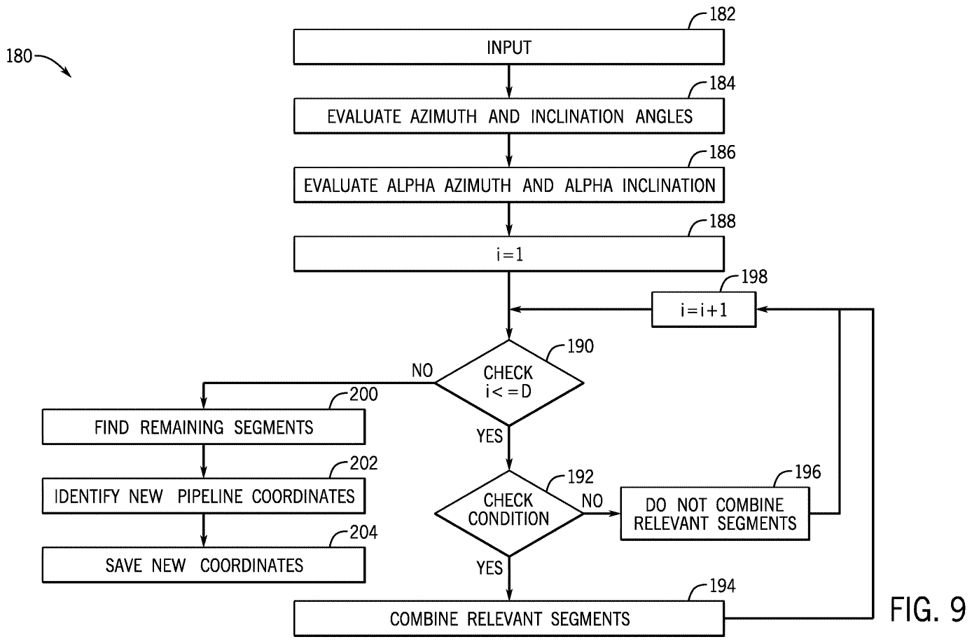

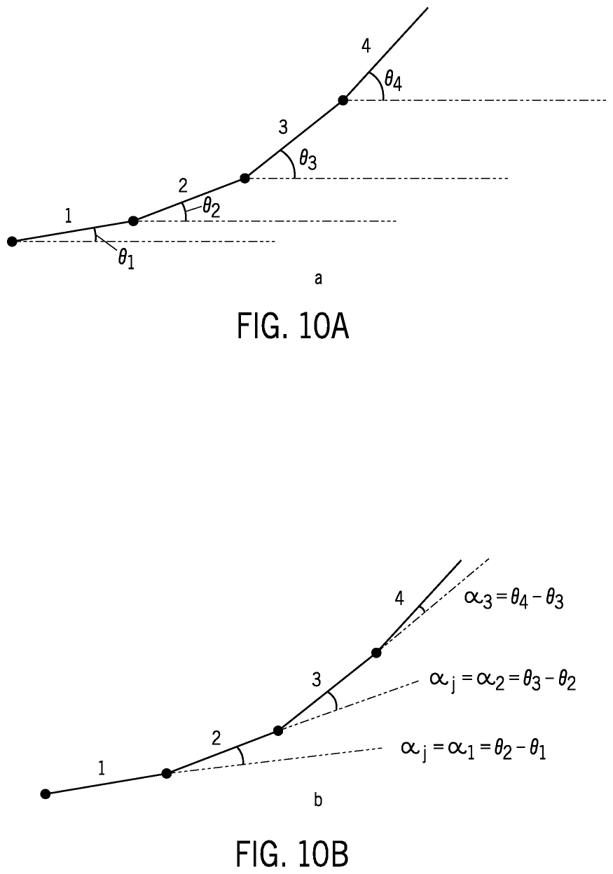

FIG. 9 is a flow diagram illustrating an embodiment of a process 180 whereby the processor 26 of the ML pipeline network modeling system 12 upscales a pipeline model. For the embodiment illustrated in FIG. 9, i is the alpha counter and D is the number of alpha values, which is equal to the number of pipeline segments of the pipeline reduced by 1. The process 180 begins with the processor 26 receiving (block 182) at least one input, including a pipeline model describing the trajectory in the form of a set of points defined by their coordinates. Prior to proceeding, the processor 26 converts these points into a series of connected pipeline segments. The process 180 continues with the processor 26 evaluating (block 184) the azimuth and inclination angles with respect to a defined reference. Subsequently, the processor 26 evaluates (block 186) the difference in azimuth and inclination angles between each of the consecutive segments, indicated as the “alpha azimuth” and the “alpha inclination” in FIG. 9. For example, FIG. 10A is a schematic representation that illustrates the upscaling angle, while FIG. 10B is a schematic representation that illustrates the alpha (α) evaluation. The alpha counter (i) is set to a value of 1 at block 188, and thus, the processor 26 determines that i is less than or equal to D in the first iteration of decision block 190.

It may be appreciated that, during the process 180, the pipeline model is upscaled depending on upscaling limits. The upscaling limits include four factors: maximum acceptable difference in azimuth angle

$$( {α}_{max}^{azimuth} ) ,$$

maximum acceptable difference in inclination angle

$$( {α}_{max}^{inclination} ) ,$$

maximum acceptable summation of difference in azimuth angle (Max_{azimuth}), and maximum acceptable summation of difference in inclination angle (Max_{inclination}). In some embodiments, these limits may be user specified as part of the inputs received at block 182.

For the embodiment illustrated in FIG. 9, the process 180 continues with the processor 26 checking a set of conditions (decision block 192) to determine whether the current pipeline segment should be combined with the subsequent pipe segment of the pipeline. At decision block 192, the processor 26 determines that the pipeline segments should be combined when the following conditions are satisfied:

$$1. {α}_{i}^{azimuth} < {α}_{max}^{azimuth}$$

$$2. {\sum }_{i = 1}^{j} {α}_{i}^{azimuth} < {Max}^{azimuth} ,$$

where i is starting position and j is current position

$$3. {α}_{i}^{inclination} < {α}_{max}^{inclination}$$

$$4. {\sum }_{i = 1}^{j} {α}_{i}^{inclination} < {Max}^{inclination}$$

For the embodiment illustrated in FIG. 9, when the processor 26 determines in decision block 192 that the pipeline segments should be combined, the processor 26 responds by combining (block 194) the relevant segments within the pipeline model. Otherwise, the processor 26 does not combine (block 196) the relevant segments. Subsequently, the processor 26 increments the value of the alpha counter (i) (block 198) and returns to decision block 190. When the processor 26 determines that i is no longer less than or equal to D at decision block 190, the processor 26 concludes the process 180 by finding (block 200) the remaining (uncombined) pipeline segments, identifying (block 202) upscaled pipeline trajectory points and coordinates for these remaining segments to yield an upscaled pipeline model, and then saving (block 204) the upscaled pipeline model (e.g., in the storage 30 of the ML pipeline network modeling system 12).

In other embodiments, one or more of the upscaling limits may be calculated or optimized in an iterative manner. For example, the processor 26 may determine an upscaling limit by first solving pressure drop through the original trajectories of the pipeline using the flow simulator, upscaling the pipeline model based on initial (default) pipeline upscaling limits, and then solving pressure drop through the upscaled trajectories of the pipeline model using the flow simulator. The processor 26 may iteratively modify one or more of the pipeline upscaling limits, re-upscale the pipeline model based on the modified pipeline upscaling limits, and solve for pressure drop through the upscaled trajectories of the pipeline model using the flow simulator, until a percentage error between the pressure drop predicted for the original trajectories of the pipeline and the pressure drop predicted for the upscaled trajectories of the pipeline model is less than a predefined threshold value.

As discussed above, in block 92 of FIG. 3, the pipeline trajectories of one or more of the pipelines of a pipeline network may optionally be upscaled before the pressure drop through the network is estimated. As noted herein, the pipeline network is a series of pipelines connected in a tree-like structure, and every pipeline is a series of connected segments. As such, the input to block 92 of FIG. 3 includes the set of trajectories of the pipelines that constitute the network. Then, in block 92 of FIG. 3, the processor 26 performs the pipeline upscaling process 180 of FIG. 9, as discussed above, to individually upscale each pipeline of the network, yielding the upscaled network model.

### Estimating Pressure Drop in a Segmented Pipeline

As discussed above, at block 82 of FIG. 3, the processor 26 applies a network solver that uses the previously developed ML models (i.e., a ML-based network solver) to estimate the pressure drops and the flow rates through the pipeline segments, as well as the pressure at every node of the pipeline model. In some embodiments, the actions of block 82 of FIG. 3 can be generally divided into a modeling stage and a solving stage, as discussed below.

At the modeling stage, the processor 26 receives inputs, including the pipeline trajectories (e.g., original or upscaled), specified boundary conditions (e.g., flow rates at inlet, pressure at outlet) and pipeline characteristics (e.g., diameter, roughness). The processor 26 begins the modeling stage by building the geometry of the pipeline. To build the geometry of the pipeline, the processor 26 identifies the geometrical characteristics of the pipeline, such as number of nodes, segments, length, inclination and azimuth angles, upstream and downstream nodes of segments, and so forth. The processor 26 also identifies the layers nodes, including system inlet nodes, system internal nodes, and system outlet nodes. Using these layers nodes, the processor 26 may clean the geometry data by removing repeated internal nodes to avoid considering the same nodes multiple times. In some embodiments, the processor 26 rearranges the geometry and layers data, and then stores the data in two separate spreadsheets. The processor 26 may subsequently combine the geometry and layers data with the boundary conditions and pipeline characteristics into a single spreadsheet.

In the solving stage, the processor 26 builds a system of equations based on the spreadsheet generated during the modeling stage. The equations include node-based equations and branch based equations. The node based equations are mass conservation equations for each component c at node i (except the system outlet node), as expressed in Equation 1:

$${\sum }_{j {ϵΩ}_{i}} {\dot{m}}_{ij}^{c} + {\dot{M}}_{i}^{c} = 0 , i = 1 , … , ( {N}_{n} - 1 ) and c = 1 , … , Nc ,$$

wherein

$${\dot{m}}_{ij}^{c}$$

is the mass flow rate of component c between node i and node j;

$${\dot{M}}_{i}^{c}$$

is the source or sink mass flow rate term of component c at node i. Positive means inlet flow rates (added into the node) and negative means outlet flow rates (withdrawn from the node);
Ωᵢ is the set of nodes connected to node i;
Nn−1 is the set of nodes excluding system outlet node; and
Nc is the set of components.

It may be noted that, with respect to

$${\dot{M}}_{i}^{c} ,$$

the adopted sign convention considers a positive sign for the flow rate entering node i and negative sign for the flow rate leaving node i. In other words, when j is upstream to node i, then the flow is entering node i and the flow rate has a positive sign; whereas, when j is downstream to node i then the flow is leaving node i then the flow rate has a negative sign.

The branch-based equation corresponds to pressure equation through each branch and is expressed in accordance with Equation 2:

$${P}_{j} = {P}_{i} - Δ {P}_{ij} ,$$

wherein i is the upstream node of branch ij;
j is the downstream node of branch ij;
Pᵢ is the pressure at node i;
Pⱼ is the pressure at node j; and
ΔPᵢⱼ is the pressure drop through branch ij; i.e. between any two connected nodes i and j.

Prior to the present disclosure, the pressure drop through a pipeline is typically evaluated using multiphase flow correlations. However, for present embodiments, the pressure drop is estimated by the ML-based network solver using the previously developed ML models. The above system of equations is solved using the Newton method. In some embodiments, the output includes two spreadsheets: one spreadsheet corresponding to the results at the flow line level, which includes component flow rates and pressure drops, and one includes the results at the node level, which corresponds to pressure values. A key benefit of the ML pipeline network modeling system 12 is its modular/flexible approach, in which ML models can be added as desired. For example, in certain embodiments, when a pressure drop is to be estimated for a pipeline, the processor 26 can select a suitable ML model for each pipeline segment from a number of differently trained ML models, each trained with respect to specific ranges for length, inclination angle, and so forth, based on the pipeline characteristics.

### Solving the Segmented Network Using a Conventional Iterative Solver

At block 102 of FIG. 4, the processor 26 receives the pipeline trajectories of the network (e.g., original or upscaled), along with user-specified boundary conditions and pipeline characteristics, and uses this information to generate a network model. The boundary conditions may include flow rates at inlet nodes and pressure at the terminal node, and the pipeline characteristics may include inner diameter and roughness of each of the pipeline segments of the network. The processor 26 applies the ML-based network solver, as discussed in the section above, which uses the previously developed ML models (e.g., FIG. 2, block 60) to estimate the pressure drops and the flow rates through each pipeline of the network, as well as the pressure at every node of the network model.

### Example Results

In a set of example studies, three surface networks of increasing complexity were evaluated using both the ML-based network solver and the flow simulator and the results were compared. In a first study, the ML pipeline network modeling system 12 generated eight ANN ML models to meet the network characteristics of the three surface networks. The ML models were developed using the process 40 of FIG. 2 to predict pressure gradient. The models covered two length ranges from 100 ft 1,000 ft and from 1,000 ft to 5,000 ft. The inclination angle ranged between −10° and 10° and was divided into four subranges: one for horizontal geometry, one for uphill geometry with a range of 0° to 10° and two for downhill geometry with ranges of from −10° to −5° and from −5° to 0°. For each length range, four models were developed as discussed above. For this study, Table 2 presents the performance of four ANN ML models for the length range between 100 ft and 1,000 ft, and Table 3 presents the performance of the four ANN ML models for the length range between 1,000 ft and 5,000 ft. As shown in Tables 2 and 3, the results of the horizontal and the uphill models were better than those of the downhill models, where its percentage of samples with percentage error less than 5% (PE<5%) did not show high values as those for horizontal and uphill models.

TABLE 2
Evaluation metrics for the training and testing phases of the ANN algorithm
used to develop the four ML models for length range between 100 and 1,000 ft.

| | Training Set | | | | | Testing Set | | | | |
|---|---|---|---|---|---|---|---|---|---|---|
| Model | R² | MSE | MAPE | MAX PE | PE <5% | R² | MSE | MAPE | MAX PE | PE <5% |
| Horizontal | 0.995 | 0.00543 | 2.84 | 73.02 | 86.31 | 0.992 | 0.00793 | 3.23 | 104.31 | 83.8 |
| Uphill | 0.994 | 0.00610 | 1.87 | 86.4 | 93.58 | 0.985 | 0.01453 | 2.2 | 109.95 | 90.75 |
| Downhill 1 | 0.994 | 0.00602 | 4.9 | 205.79 | 72.97 | 0.993 | 0.00696 | 5.47 | 114.25 | 69.82 |
| Downhill 2 | 0.992 | 0.0088 | 7.8 | 238.38 | 58.13 | 0.991 | 0.0099 | 8.56 | 217.03 | 55.58 |

TABLE 3
Evaluation metrics for the training and testing phases of the ANN algorithm used
to develop the four ML models for length range between 1,000 and 5,000 ft.

| | Training Set | | | | | Test Set | | | | |
|---|---|---|---|---|---|---|---|---|---|---|
| | | | | MAX | | | | | MAX | |
| Model | R² | MSE | MAPE | PE | PE <5% | R² | MSE | MAPE | PE | PE <5% |
| Horizontal | 0.998 | 0.00153 | 1.96 | 40.73 | 91.86 | 0.998 | 0.00204 | 2.17 | 35.12 | 90.5 |
| Uphill | 0.997 | 0.00298 | 1.67 | 37.18 | 95.05 | 0.997 | 0.00346 | 1.79 | 48.27 | 94.53 |
| Downhill 1 | 0.997 | 0.00265 | 4.45 | 177.17 | 77.36 | 0.997 | 0.00323 | 4.32 | 110.47 | 77.27 |
| Downhill 2 | 0.999 | 0.00137 | 5.26 | 145.43 | 69.47 | 0.998 | 0.00173 | 5.57 | 161.07 | 67.21 |

In a second study, the ML pipeline network modeling system 12 generated a single ML model (instead of multiple ML models) using the datasets previously developed to cover the ranges under study. That is, the eight datasets of the first study were combined into a single, large dataset. The three ML algorithms (SVR, RF, and ANN) were trained and their results are represented in Table 4. As a result, the single ML model became characterized by a length range between 100 ft and 5000 ft and an inclination angle range between −10° and 10°. The single ANN ML model demonstrated good performance in both the training and the testing phases, where 87.9% of the samples in each phase showed a percentage error below 5%, as indicated in Table 4.

TABLE 4
Evaluation metrics for the training and testing phases of the
three ML algorithms trained to develop the single ML model.

| | Training Set | | | | | Testing Set | | | | |
|---|---|---|---|---|---|---|---|---|---|---|
| | | | | MAX | | | | | MAX | |
| Model | R² | MSE | MAPE | PE | PE <5% | R² | MSE | MAPE | PE | PE <5% |
| SVR | 0.996 | 0.00359 | 7.89 | 245.55 | 56.65 | 0.996 | 0.00403 | 8.07 | 398.69 | 56.01 |
| RF | 0.999 | 0.00041 | 2.00 | 383.37 | 92.15 | 0.997 | 0.00313 | 5.45 | 428.73 | 74.07 |
| ANN | 0.999 | 0.00088 | 2.49 | 91.18 | 87.89 | 0.999 | 0.00095 | 2.52 | 119.11 | 87.9 |

The ML-based network solver, whether using a single ML model or multiple ML models, demonstrated systematically excellent results relative to those of the flow simulator. For the three surface networks under study, the average percentage error (PE) for pressure drop estimation using the multiple ML models of the first study was approximately 1.80%, while the average PE for the pressure drop estimation using the single ML model of the second study was approximately 1.86%. Additionally, in terms of the average PE in the estimated pressure at the inlet nodes of the pipelines of the surface networks, the multiple ML models of the first study demonstrated a value of approximately 0.52%, while the single ML model of the second study demonstrated a value of approximately 0.42%.

For these studies, both the single and multiple ML-based network solvers reached the same component flow rates values as the flow simulator through the different pipelines of each network. The percentage errors were zero for the steady state oil, gas, and water flow rates. As for the processing time, Table 5 indicates that the ML-based network solver, whether using the multiple ML models of the first study or the single ML model of the second study, outperformed the flow simulator performance. For the same number of iterations, the single ML-based solver was faster than the one using multiple ML models, since multiple inputs can be passed to the ML model at a time instead of passing a single input.

TABLE 5
Number of segments, the ML-based network solver iterations, and the
processing time used in the multiple ML network solver of the first study,
the single ML network solver of the second study, and the flow simulator,
to solve the three surface networks under study.

| | Case 1 | Case 2 | Case 3 |
|---|---|---|---|
| Number of pipeline segments | 186 | 245 | 559 |
| Single ML-based solver - Number of iterations | 6 | 4 | 4 |
| Single ML-based solver - Processing time (s) | 10 | 11 | 41 |
| Multiple ML-based solver - Number of | 6 | 4 | 4 |
| iterations | | | |
| Multiple ML-based solver - Processing time (s) | 16 | 15 | 45 |
| Flow simulator processing time (s) | 130 | 200 | 866 |

In a third study, the three networks of the first two studies were then upscaled, as discussed above, and the performance of the multiple ML models of the first study and the single ML model of the second study was evaluated with respect to the upscaled network models. The networks were upscaled by approximately 60% while keeping the topology representative of original one and the difference in pressure drop below 1%. The upscaled networks were also solved by the ML based network solver using the single and the multiple ML models, and the results compared to those of the flow simulator. Like the results of the first and second studies, both ML based solvers resulted in a zero percentage error for component flow rates for all pipelines of the upscaled network models. For pressure drop, the single ML model and the multiple ML models demonstrated average PE values of 1.95% and 2.20%, respectively. For the pressure at the inlet nodes, the single ML model demonstrated an average PE value of 0.43%, while the multiple ML models demonstrated an average PE value of 0.58%.

For the third study, Table 6 indicates the processing time taken by the single ML-based network solver, the multiple ML based network solver, and the flow simulator to solve the three upscaled network models. It is clear that the upscaling method effectively accelerates the process of modeling and solving the networks. The processing time decreased by up to 78.5% for both the simulator and the ML-based network solvers. While the processing time for the flow simulator was lessened by upscaling, the ML-based network solvers remained faster.

TABLE 6
Number of segments, the ML-based network solver iterations, and the
processing time used in the single ML network solver, the multiple ML
network solver, and the flow simulator to solve the upscaled networks
under study.

| | Case 1 | Case 2 | Case 3 |
|---|---|---|---|
| Number of pipeline segments | 74 | 98 | 228 |
| Single ML-based solver - Number of | 6 | 4 | 4 |
| iterations | | | |
| Single ML-based solver - Processing | 8 | 4 | 9 |
| time (s) | | | |
| Multiple ML-based solver - Number of | 5 | 4 | 5 |
| iterations | | | |
| Multiple ML-based solver - Processing | 11 | 11 | 18 |
| time (s) | | | |
| Flow simulator processing time (s) | 38 | 54 | 180 |

While only certain features of disclosed embodiments have been illustrated and described herein, many modifications and changes will occur to those skilled in the art. It is, therefore, to be understood that the appended claims are intended to cover all such modifications and changes as fall within the true spirit of the present disclosure.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

What is claimed is:

1. A method, comprising:
sampling a multidimensional physical space to determine representative combinations of pipeline segment parameters;
executing a flow simulator to estimate pressure drop values or pressure gradient values for pipeline segments having the representative combinations of pipeline segment parameters;
using the pressure drop values or the pressure gradient values estimated by the flow simulator to train a ML model to predict pressure drop values or pressure gradient values for the pipeline segments having the representative combinations of pipeline segment parameters, yielding a trained ML model; and
using the trained ML model in predictive mode by providing, as input to the trained ML model, input values representing the pipeline segment parameters of a pipeline segment, and in response, receiving, as output, a corresponding predicted pressure drop value or a corresponding predicted pressure gradient value for the pipeline segment.

2. The method of claim 1, wherein using the trained ML model in predictive mode comprises:
executing a ML-based network solver to estimate a pressure drop value, a flow rate value, and node pressure values for a pipeline model representing a plurality of pipeline segments coupled together via a plurality of nodes, wherein, during execution, the ML-based network solver uses the trained ML model in predictive mode to determine the corresponding predicted pressure drop value or the corresponding predicted pressure gradient value for each of the plurality of pipeline segments of the pipeline model.

3. The method of claim 2, comprising:
upscaling the pipeline model before executing the ML-based network solver, wherein a number of pipeline segments in the pipeline model is reduced during upscaling, and a topology of the pipeline model remains representative of an original pipeline trajectory of the pipeline model prior to upscaling.

4. The method of claim 1, wherein using the trained ML model in predictive mode comprises:
executing a ML-based network solver to estimate a pressure drop value, a flow rate value, and node pressure values for a pipeline network model, wherein the pipeline network model represents a plurality of pipelines, each having a plurality of pipeline segments coupled together via a plurality of nodes, wherein, during execution, the ML-based network solver uses the trained ML model in predictive mode to determine the corresponding predicted pressure drop value or the corresponding predicted pressure gradient value for each of the plurality of pipeline segments of each of the plurality of pipelines of the pipeline network model.

5. The method of claim 4, further comprising:
upscaling the pipeline network model before executing the ML-based network solver, wherein a number of pipeline segments in the plurality of pipelines of the pipeline network model is reduced during upscaling, and a topology of the pipeline network model remains representative of original pipeline trajectories of the pipeline network model prior to upscaling.

6. The method of claim 1, wherein the ML model is a random forest (RF) ML model, a support vector regression (SVR) ML model, or an artificial neural network (ANN) ML model.

7. The method of claim 1, wherein sampling comprises applying a Latin hypercube sampler to sample the multidimensional physical space and determine the representative combinations of pipeline segment parameters.

8. The method of claim 1, wherein the pipeline segment parameters comprise an outlet pressure, an inclination angle, an inner diameter (ID), an inlet liquid flow rate, and a pipeline segment length.

9. The method of claim 8, wherein the pipeline segment parameters comprise an gas-oil ratio, inlet temperature, water cut, roughness, oil American Petroleum Institute (API) gravity, water specific gravity, gas specific gravity, wall thickness, or rate of undulations.

10. The method of claim 1, wherein training the ML model comprises:
using the pressure drop values or the pressure gradient values estimated by the flow simulator to train a plurality of ML models to predict pressure drop values or pressure gradient values for the pipeline segments having the representative combinations of pipeline segment parameters, yielding a plurality of trained ML models, wherein each of the plurality trained ML models is trained using a subset of the representative combinations of pipeline segment parameters for which at least one of the pipeline segment parameters falls within a predefined range of values.

11. The method of claim 10, wherein each subset of the representative combinations of pipeline segment parameters corresponds to a respective predefined range of pipeline segment length values.

12. A machine learning (ML) pipeline network modeling system, comprising:
at least one memory configured to store a flow simulator; and
at least one processor configured to execute stored instruction to perform actions comprising:
sampling a multidimensional physical space to determine representative combinations of pipeline segment parameters;
executing the flow simulator to estimate pressure drop values or pressure gradient values for pipeline segments having the representative combinations of pipeline segment parameters;
using the pressure drop values or the pressure gradient values estimated by the flow simulator to train a ML model to predict pressure drop values or pressure gradient values for the pipeline segments having the representative combinations of pipeline segment parameters, yielding a trained ML model; and
using the trained ML model in predictive mode by providing, as input to the trained ML model, input values representing the pipeline segment parameters of a pipeline segment, and in response, receiving, as output, a corresponding predicted pressure drop value or a corresponding predicted pressure gradient value for the pipeline segment.

13. The ML pipeline network modeling system of claim 12, wherein the at least one memory is configured to store a ML-based network solver, and wherein using the trained ML model in predictive mode comprises:
receiving a pipeline model representing a plurality of pipeline segments coupled together via a plurality of nodes;
upscaling the pipeline model, wherein a number of pipeline segments in the pipeline model is reduced during upscaling, and a topology of the pipeline model remains representative of an original pipeline trajectory of the pipeline model prior to upscaling; and
executing the ML-based network solver to estimate a pressure drop value, a flow rate value, and node pressure values for the pipeline model, wherein, during execution, the ML-based network solver uses the trained ML model in predictive mode to determine the corresponding predicted pressure drop value or the corresponding predicted pressure gradient value for each of the plurality of pipeline segments of the pipeline model.

14. The ML pipeline network modeling system of claim 12, wherein the at least one memory is configured to store a ML-based network solver, and wherein using the trained ML model in predictive mode comprises:
receiving a pipeline network model, wherein the pipeline network model represents a plurality of pipelines, each having a plurality of pipeline segments coupled together via a plurality of nodes;
upscaling the pipeline network model, wherein a number of pipeline segments in the plurality of pipelines of the pipeline network model is reduced during upscaling, and a topology of the pipeline network model remains representative of original pipeline trajectories of the pipeline network model prior to upscaling; and
executing the ML-based network solver to estimate a pressure drop value, a flow rate value, and node pressure values for a pipeline network model, wherein, during execution, the ML-based network solver uses the trained ML model in predictive mode to determine the corresponding predicted pressure drop value or the corresponding predicted pressure gradient value for each of the plurality of pipeline segments of each of the plurality of pipelines of the pipeline network model.

15. The ML pipeline network modeling system of claim 12, wherein the pipeline segment parameters comprise an outlet pressure, an inclination angle, an inner diameter (ID), an inlet liquid flow rate, and a pipeline segment length.

16. A non-transitory, computer-readable medium storing instructions executable by a processor of a computing device, wherein the instructions comprise instructions to:
sample a multidimensional physical space to determine representative combinations of pipeline segment parameters;
execute a flow simulator to estimate pressure drop values or pressure gradient values for pipeline segments having the representative combinations of pipeline segment parameters;
use the pressure drop values or the pressure gradient values estimated by the flow simulator to train a ML model to predict pressure drop values or pressure gradient values for the pipeline segments having the representative combinations of pipeline segment parameters, yielding a trained ML model; and
use the trained ML model in predictive mode by providing, as input to the trained ML model, input values representing the pipeline segment parameters of a pipeline segment, and in response, receiving, as output, a corresponding predicted pressure drop value or a corresponding predicted pressure gradient value for the pipeline segment.

17. The non-transitory, computer-readable medium claim 16, wherein the instructions to use the trained ML model in predictive mode comprise instructions to:
receive a pipeline model representing a plurality of pipeline segments coupled together via a plurality of nodes;
upscale the pipeline model, wherein a number of pipeline segments in the pipeline model is reduced during upscaling, and a topology of the pipeline model remains representative of an original pipeline trajectory of the pipeline model prior to upscaling; and
execute a ML-based network solver to estimate a pressure drop value, a flow rate value, and node pressure values for the pipeline model, wherein, during execution, the ML-based network solver uses the trained ML model in predictive mode to determine the corresponding predicted pressure drop value or the corresponding predicted pressure gradient value for each of the plurality of pipeline segments of the pipeline model.

18. The non-transitory, computer-readable medium of claim 16, wherein the instructions to use the trained ML model in predictive mode comprise instructions to:
receive a pipeline network model, wherein the pipeline network model represents a plurality of pipelines, each having a plurality of pipeline segments coupled together via a plurality of nodes;
upscale the pipeline network model, wherein a number of pipeline segments in the plurality of pipelines of the pipeline network model is reduced during upscaling, and a topology of the pipeline network model remains representative of original pipeline trajectories of the pipeline network model prior to upscaling; and
execute a ML-based network solver to estimate a pressure drop value, a flow rate value, and node pressure values for a pipeline network model, wherein, during execution, the ML-based network solver uses the trained ML model in predictive mode to determine the corresponding predicted pressure drop value or the corresponding predicted pressure gradient value for each of the plurality of pipeline segments of each of the plurality of pipelines of the pipeline network model.

19. The non-transitory, computer-readable medium of claim 16, wherein the instructions to train the ML model comprise instructions to:
use the pressure drop values or the pressure gradient values estimated by the flow simulator to train a plurality of ML models to predict pressure drop values or pressure gradient values for the pipeline segments having the representative combinations of pipeline segment parameters, yielding a plurality of trained ML models, wherein each of the plurality trained ML models is trained using a subset of the representative combinations of pipeline segment parameters having respective pipeline segment lengths falling within a predefined range of values.

20. The non-transitory, computer-readable medium of claim 16, wherein the pipeline segment parameters comprise an outlet pressure, an inclination angle, an inner diameter (ID), an inlet liquid flow rate, and a pipeline segment length, and optionally comprises one or more of an gas-oil ratio, inlet temperature, a water cut, roughness, oil American Petroleum Institute (API) gravity, water specific gravity, gas specific gravity, wall thickness, and rate of undulations.
